(19) United States
(12) Patent Application Publication
(10) Pub. No.: US 2024/0377723 A1
(43) Pub. Date: Nov. 14, 2024

(54) COMPUTER IMPLEMENTED METHOD AND SYSTEM FOR SIMULATING AN AERIAL IMAGE OF A PHOTOLITHOGRAPHY MASK

(71) Applicant: Carl Zeiss SMT GmbH, Oberkochen (DE)

(72) Inventors: Niklas Georg, Haiger (DE); Martin Van Driel, Muenchen (DE)

(21) Appl. No.: 18/650,841

(22) Filed: Apr. 30, 2024

(30) Foreign Application Priority Data
May 5, 2023 (DE) 10 2023 111 854.4

(51) Int. Cl. G03F 1/36; G03F 7/00

(52) U.S. Cl. CPC G03F 1/36; G03F 7/70133; G03F 7/70666; G03F 7/706831; G03F 7/706837; G03F 7/706841

(57) ABSTRACT

A computer implemented method for simulating an aerial image of a design of a photolithography mask comprises: obtaining an illumination angle distribution in the pupil plane of the light source; selecting a number of illumination angles by solving an optimization problem; for each selected illumination angle, simulating an electromagnetic near field; for at least one further illumination angle of the illumination angle distribution in the pupil plane of the light source approximating an electromagnetic near field; and obtaining the simulated aerial image of the design of the photolithography mask by superimposing the intensities obtained by imaging the electromagnetic near fields into a wafer plane. Systems can detect defects or assess the relevance of defects or for aligning aerial images.

### CROSS-REFERENCE TO RELATED APPLICATION

This application claims benefit under 35 U.S.C. § 119 (a) of German patent application No. 10 2023 111 854.4 filed May 5, 2023. The entire disclosure of this application is incorporated by reference herein.

### FIELD

The disclosure relates to a computer implemented method, a computer-readable medium, a computer program product and corresponding systems for simulating aerial images of photolithography masks. The method, computer-readable medium, computer program product and systems can be utilized for quantitative metrology, defect detection in photolithography masks, assessment of defect relevance in photolithography masks, aerial image alignment, photolithography mask improvement, system simulation or for process control, process monitoring and/or process improvement.

### BACKGROUND

A wafer made of a thin slice of silicon can serve as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. A part of the process is the photolithography process.

Photolithography is a process used to produce patterns on the substrate of a wafer. The patterns to be printed on the surface of the substrate are usually generated by computer-aided-design (CAD). From the design, for each layer a photolithography mask is generated, which contains a magnified image of the computer-generated pattern to be etched into the substrate. The photolithography mask can be further adapted, e.g., using optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers. In the past, when photolithography involved less precision, the circuit layout equaled the mask pattern which equaled the wafer pattern.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 20 nm, for example 10 nm, 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer involves photolithography masks or templates for nanoimprint photolithography with ever smaller structures or pattern elements. The production process of photolithography masks and templates for nanoimprint photolithography is, therefore, becoming increasingly more complex and, as a result, more time-consuming and ultimately also more expensive. With the advent of EUV photolithography scanners, the nature of masks changed from transmission-based patterning to reflection-based patterning.

Today, the minimum feature size on the mask has reached sub-wavelength dimensions. Consequently, the so-called optical proximity effect caused by non-uniformity of energy intensity due to optical diffraction during the exposure process occurs. As a result, images formed on the substrate do not faithfully reproduce the patterns on the photolithography mask.

Therefore, many applications involve an aerial image of the photolithography mask, which simulates the radiation intensity distribution at the substrate level. In this way, the aerial image allows for an analysis of the semiconductor structures that will be printed onto the substrate during the printing process without actually having to print a wafer. However, the generation of an aerial image is time-consuming and expensive. Therefore, accurate and fast methods for simulating aerial images based on a design of a photolithography mask have become important.

Among these methods, there are time-consuming rigorous simulations such as finite difference time domain (FDTD) or rigorous coupled wave analysis (RWCA), and fast approximations such as the thin element approximation (TEA). Due to the heavy computational load for full-chip applications, rigorous simulation is not typically used in commercial computational photolithography software. The thin element approximation (TEA) assumes that the thickness of the structures on the photolithography mask is very small compared to the wavelength, and that the widths of the structures on the photolithography mask are very large compared to the wavelength. However, as lithographic processes use radiation of shorter and shorter wavelengths, and the structures on the patterning device become smaller and smaller and grow into the vertical dimension, these assumptions do not hold anymore. Interaction of the incoming radiation with the absorber structures leads to mask 3D effects, which is to be considered by the simulation. Therefore, the TEA yields inaccurate aerial images for radiation of short wavelength. In order to obtain simulations of aerial images, which are accurate and fast, further approximations to the rigorous simulations have been devised, for example the method disclosed in PCT/EP2023/087651 or DE 10 2022 135 019.3, which are hereby incorporated herein by reference in their entirety.

Especially for reflection-based EUV photolithography masks, but also for transmission-based photolithography masks, the illumination angle of light or radiation that illuminates the mask can be taken into account. Illumination angle distributions can be represented by source maps, which may be simple geometric shapes such as annular, quadrupole, dipole, etc., or customized for specific layouts of integrated circuits on the photolithography mask.

Different approaches are known for computing the image intensity of the aerial image for different illumination angles, for example the Hopkins approach and the Abbe approach.

The Hopkins approach relies on the observation that for small variations of the incidence angles of the light waves only very small deviations of the intensity, phase and polarization of the light waves can be expected. Thus, a change in the illumination angle approximately only results in a frequency shift of the respective diffraction spectrum of the photolithography mask. The same mask spectrum [symbol] {Eⁱⁿ(x, y)} of an incoming electromagnetic near field Eⁱⁿ(x, y) is, therefore, used for all illumination angles with a shift according to the illumination angle:

$${I}^{out} ( {x}^{′} , {y}^{′} ) = 0.5 {ϵ}^{0} \text{} {c}^{0} \text{} {\sum }_{i = 1}^{{N}_{Abbe}} \hat{J} ( {f}_{x , i}^{illu} , {f}_{y , i}^{illu} ) {\vert \{ \{ {E}^{in} ( x , y ) \} ( {f}^{x} - {f}_{x , i}^{illu} , {f}^{y} - {f}_{y , i}^{illu} ) \hat{P} ( {f}^{x} , {f}^{y} ) \} \vert}^{2} ,$$

where I^{out}(x′, y′) indicates the intensity of the aerial image, \hat{P}(f^{x}, f^{y}) a complex imaging pupil function, Ĵ(f_{x,i}^{illu}, f_{y,i}^{illu}) an illumination angle weighting distribution (e.g., with respect to the illumination intensity), ϵ⁰ the electric permittivity, c⁰ the speed of light assuming vacuum, f_{x,i}^{illu}, f_{y,i}^{illu} the illumination angles and N_{Abbe} the number of illumination angles in the illumination angle distribution in the pupil plane.

This approach is simple and fast. For simulations using the thin mask or Kirchhoff approach such as the TEA this assumption is always fulfilled. However, in case that the thickness of the structures on the photolithography mask cannot be neglected anymore and involve rigorous electromagnetic field simulations of mask diffraction for varying illumination angles, the Hopkins approach may not be sufficiently accurate.

In this case the Abbe approach may be used to accommodate for the non-constant diffraction spectra of the photolithography mask, since the Abbe approach assumes illumination angle dependent diffraction spectra [symbol] {E^{in,i}}, i=1, . . . N_{Abbe}:

$${I}^{out} ( {x}^{′} , {y}^{′} ) = 0.5 {ϵ}^{0} {c}^{0} {\sum }_{i = 1}^{{N}_{Abbe}} \hat{J} ( {f}_{x , i}^{illu} , {f}_{y , i}^{illu} ) {\vert \{ \{ {E}^{in , i} ( x , y ) \} ( {f}^{x} , {f}^{y} ) \hat{P} ( {f}^{x} , {f}^{y} ) \} \vert}^{2} .$$

However, the Abbe approach is highly computationally expensive, since an electromagnetic near field has to be simulated for every single illumination angle. Thus, the Abbe approach may not be suitable for use in, e.g., a simulation of a full-chip capable optical proximity correction (OPC) or verification system.

In order to obtain a fast and accurate simulation method for aerial images of photolithography masks, the local Hopkins approach can be used as disclosed, for example, in US 2007/0253637 A1. The local Hopkins approach is a combination of the Hopkins approach and the Abbe approach based on locally assuming constant diffraction spectra of the photolithography mask. To this end, the source maps are partitioned into a number of segments. For each segment the diffraction spectra are assumed constant, such that only a single diffraction spectrum for each segment has to be simulated. Hence, with the local Hopkins approach, a smaller number of spectra [symbol] {E^{in,j}}, j=1, . . . N_{Hop}, N_{Hop}<<N_{Abbe}, for a subset of selected illumination angles is simulated. For the remaining illumination angles the simulated spectra are shifted according to the illumination angle:

$${I}^{out} ( {x}^{′} , {y}^{′} ) = 0.5 {ϵ}^{0} {c}^{0} {\sum }_{j = 1}^{{N}_{Hop}} {\sum }_{i = 1}^{{N}_{Abbe , j}} \hat{J} ( {f}_{x , i}^{illu} , {f}_{y , i}^{illu} ) {\vert \{ \{ {E}^{in , j} ( x , y ) \} ( {f}^{x} - Δ {f}_{x , i , j}^{illu} , {f}^{y} - Δ {f}_{y , i , j}^{illu} ) \hat{P} ( {f}^{x} , {f}^{y} ) \} \vert}^{2} ,$$

$$where Δ {f}_{x , i , j}^{illu} = {f}_{x , i}^{illu} - {f}_{x , i , j}^{illu , Hop} and Δ {f}_{y , i , j}^{illu} = {f}_{y , i}^{illu} - {f}_{y , i , j}^{illu , Hop} .$$

However, the local Hopkins approach can involve a careful selection of segments and illumination angles within the segments, for which the diffraction spectra are simulated. In US 2007/0253637 A1, for example, the segments as well as the illumination angles are selected by the user. This procedure can lead to sub-optimal aerial image simulations and involve time and user effort.

### SUMMARY

This disclosure seeks to provide an accurate approach for the simulation of aerial images involving low computation times. The disclosure also seeks to reduce the user effort for the simulation of aerial images. Further, the disclosure seeks to repeatably simulate aerial images. In addition, the disclosure seeks provide an aerial image simulation method which is applicable to transmission-based and reflection-based photolithography masks. The disclosure also seeks to improve photolithography mask design without the need to actually print a wafer. Moreover, the disclosure seeks to detect defects in photolithography masks with high accuracy and at low computation times. Further, the disclosure seeks to assess the relevance of defects detected in photolithography masks with high accuracy and at low computation times. Also, the disclosure seeks to prevent defects in wafers by accurately aligning subsequently printed layers.

Embodiments of the disclosure can concern computer implemented methods, a non-transitory computer-readable medium, a computer program product, and corresponding systems for simulating aerial images of a design of a photolithography mask or for detecting defects or assessing the relevance of defects in photolithography masks or for aligning aerial images.

In a first embodiment, the disclosure provides a computer implemented method for simulating an aerial image of a design of a photolithography mask in a photolithography system, the photolithography mask being illuminated by an illuminating optical unit by using a light source emitting illuminating radiation, the illuminating optical unit having a pupil plane. The method comprises: obtaining an illumination angle distribution in the pupil plane of the light source; selecting a number of illumination angles from the illumination angle distribution by solving an optimization problem; for each selected illumination angle, simulating an electromagnetic near field of the design of the photolithography mask illuminated by incident electromagnetic waves of the selected illumination angle in a near field plane; for at least one further illumination angle of the illumination angle distribution in the pupil plane of the light source, which was not selected, approximating an electromagnetic near field of the design of the photolithography mask illuminated by incident electromagnetic waves of the respective illumination angle using the simulated electromagnetic near fields for the selected illumination angles; and obtaining the simulated aerial image of the design of the photolithography mask by superimposing the intensities obtained by imaging the simulated electromagnetic near fields and the at least one approximated electromagnetic near field into a wafer plane.

The simulated aerial image of the design of the photolithography mask can be used for the purpose of manufacturing a photolithography mask according to an improved design of the photolithography mask. The simulated aerial image of the design of the photolithography mask can also be used for detecting defects or assessing the relevance of defects in photolithography masks. In addition, the simulated aerial image of the design of the photolithography mask can be used during the wafer printing process, such as for the purpose of preventing alignment defects in wafers.

The wafer plane is a boundary plane comprising the surface of a photoresist film on a substrate of the wafer, on which the electromagnetic waves impinge in the photolithography system. In this way, the accurate and fast simulation of the electromagnetic near field according to a method of the first embodiment of the disclosure can be used to obtain an accurate and fast simulation of an aerial image of the photolithography mask.

The selected illumination angles are obtained by solving an optimization problem. Thus, the selected illumination angles are optimized with respect to some criterion, e.g., with respect to the accuracy of the simulated aerial image and/or to the computation time of the method for simulating an aerial image of a design of a photolithography mask. In an example (explained later in greater detail, see descriptions of FIG. 7 and FIG. 8), an optimized selection of around 0.3%, of the illumination angles in the illumination pupil is already sufficient to simulate an aerial image of suitable accuracy. Accordingly, compared to the Abbe approach, a speedup of a factor of more than 300 can be obtained. In that example, it is also shown that the optimized selection of illumination angles can lead to an improved accuracy of the simulated aerial images compared to an equidistant selection of illumination angles., e.g., if using k-means clustering of the illumination angle distribution in the optimization problem. Alternatively, an aerial image of comparable accuracy can be simulated at lower computation times using less but optimally selected illumination angles. The method can work for arbitrary illumination angle distributions, also for anamorphic or free-form illumination angle distributions.

According to an example of the first embodiment of the disclosure, the illumination angle distribution is subsampled to generate a discrete set of illumination angles corresponding to electromagnetic plane waves which fulfill periodic boundary conditions in the near field plane. As fast Fourier Transforms, which can be used for simulating an aerial image with reduced computation time, assume periodic boundary conditions, the computation time can, thus, be reduced and the accuracy of the simulated aerial image can be improved.

According to an example of the first embodiment of the disclosure, the optimization problem comprises optimizing an objective function containing a measurement related to the approximation error of the simulated aerial image. The measurement can be directly related to the approximation error, for example, comprise a deviation of the simulated aerial image from a reference aerial image. Or the measurement can indirectly be related to the approximation error, e.g., by measuring the largest deviation of an illumination angle of the illumination angle distribution in the illumination pupil from the closest selected illumination angle. In this way, the accuracy of the simulated aerial image can be improved.

According to an example of the first embodiment of the disclosure, the optimization problem comprises optimizing the number of selected illumination angles. In this way, the number of selected illumination angles and, thus, the computation time can be reduced.

According to an example of the first embodiment of the disclosure, the optimization problem comprises a deviation of one or more closest selected illumination angles from one or more further illumination angles in the illumination pupil. For example, the optimization problem comprises the maximum deviation of a further illumination angle from any of the selected illumination angles, thereby minimizing the deviation of illumination angles from the selected illumination angles within the same segment. In this way, the accuracy of the simulated aerial image can be improved.

According to an example of the first embodiment of the disclosure, optimization comprises clustering illumination angles of the illumination angle distribution in the pupil plane, e.g., using a clustering method such as k-means clustering, mean shift clustering, hierarchical clustering or machine learning. In this way, the accuracy of the simulated aerial image can be improved and the computation time reduced.

According to an aspect of the example of the first embodiment of the disclosure, the optimization problem comprises a hierarchical clustering of the illumination angles of the illumination angle distribution in the pupil plane. A hierarchical clustering generates a tree of clusterings with respect to a cluster distance measure. The number of clusters within a clustering increases closer to the leaves. Using a hierarchical clustering can be beneficial because it can simplify selecting the number of illumination angles for a user or automatically by defining an optimality criterion depending on distances within or between clusters. For example, an agglomerative clustering method can be used, which merges two clusters according to a cluster distance measure. For example, two clusters can be selected for merging by minimizing the maximum illumination angle deviation within each cluster. On each tree level, a clustering of the illumination angle distribution with different numbers of clusters can be obtained. One of these clusterings can be selected, e.g., by a user or by specifying a desired number of clusters or automatically by optimizing some kind of optimality criterion of the clusterings, e.g., by defining a threshold for the maximum deviation of two illumination angles within the same cluster or a maximum distance between two illumination angles in the illumination pupil plane. The selected clustering can be easily adapted by moving from one tree level to the next.

Each tree level, thereby, represents a set of clusters of illumination angles. The number of clusters increases closer to the leaves. Thus, in order to increase the number of selected illumination angles, the number of clusters is increased by selecting a clustering corresponding to a higher tree level. In order to decrease the number of selected illumination angles, the number of clusters is reduced by selecting a clustering corresponding to a lower tree level. A user interface can be configured to visualize the cluster tree or a subsection of the cluster tree to a user and let the user select a suitable clustering. From each cluster of the selected clustering an illumination angle can be selected automatically or by user selection, e.g., the centroid of the cluster.

According to an example of the first embodiment of the disclosure, the optimization problem comprises a deviation of the obtained simulated aerial image from a reference aerial image. The deviation can, for example, be measured by the root mean squared error of the intensities or by the maximum intensity deviation. The reference aerial image can, for example, be a rigorously simulated aerial image or a simulated aerial image using the local Hopkins approach with a larger number of segments N_{Hop}. In this way, the accuracy of the simulated aerial image can be improved.

According to an example of the first embodiment of the disclosure, the optimization problem comprises the illumination intensity for different illumination angles of the illumination angle distribution. For example, the illumination intensity can be used as a weighting factor in the optimization problem, e.g., by assigning a higher weight to illumination angles with higher illumination intensity. Thus, illumination angles with higher illumination intensity have more impact on the illumination angle selection, thereby improving the accuracy of the simulated aerial image.

According to an aspect of the example of the first embodiment of the disclosure, the optimization problem adapts the distribution of the selected illumination angles with respect to the illumination intensity of the illumination angle distribution. For example, the density of the selected illumination angles can be higher in regions of the illumination pupil with higher illumination intensity. Due to the higher density of selected illumination angles within regions of higher illumination intensity the segments within these regions are smaller. Thus, the approximation of the electromagnetic near fields for further illumination angles, which were not selected, is more accurate in these regions of the illumination pupil with higher illumination intensity. Therefore, the accuracy of the simulated aerial image is improved.

According to an example of the first embodiment of the disclosure, the optimization problem comprises training a machine learning model, which uses the illumination angle distribution as input and generates a number of selected illumination angles as output.

Machine learning is a field of artificial intelligence. Machine learning methods generally build a parametric machine learning model based on training data consisting of a large number of samples. After training, the method is able to generalize the knowledge gained from the training data to new previously unencountered samples, thereby making predictions for new data. There are many machine learning methods, e.g., linear regression, k-means, support vector machines, neural networks or deep learning approaches.

Deep learning is a class of machine learning that uses artificial neural networks with numerous hidden layers between the input layer and the output layer. Due to this complex internal structure the networks are able to progressively extract higher-level features from the raw input data. Each level learns to transform its input data into a slightly more abstract and composite representation, thus deriving low-level and high-level knowledge from the training data. The hidden layers can have differing sizes and tasks such as convolutional or pooling layers.

By using a number of illumination pupils and illumination angle distributions with corresponding selected illumination angles as training data the machine learning model learns to generalize the learned knowledge to automatically select illumination angles for new illumination angle distributions and illumination pupils, which are not part of the training data. The training data can, for example, comprise selected illumination angles obtained by solving an optimization problem as described above or using exhaustive search (i.e., finding the best combination of selected illumination angles by computing the simulation error for each possible illumination angle combination and selecting the one with the lowest simulation error).

According to an example of the first embodiment of the disclosure, approximating an electromagnetic near field of the design of the photolithography mask for a further illumination angle, which was not selected, comprises shifting the mask spectrum of the simulated electromagnetic near field of the closest selected illumination angle. This approximation corresponds to the local Hopkins approach. Since for small variations of the incidence angles of the light waves only very small deviations of the intensity, phase and polarization of the light waves can be expected, the local Hopkins approach can allow for an accurate approximation of the electromagnetic near fields while considerably reducing the computation time.

According to an example of the first embodiment of the disclosure, approximating an electromagnetic near field of the design of the photolithography mask for a further illumination angle, which was not selected, comprises interpolation or regression of mask spectra of simulated electromagnetic near fields, e.g., by linear or quadratic or higher order interpolation, radial basis function interpolation or spline fitting. By interpolation or regression of simulated mask spectra for the selected illumination angles, mask spectra for further illumination angles can be obtained with low approximation error. At the same time, the computation time for simulating aerial images can be considerably reduced.

According to an example of the first embodiment of the disclosure, the number of selected illumination angles is below 2%, such as below 1%, for example below 0.5% of the illumination angles in the illumination pupil plane. In this way, the computation time is reduced while still obtaining a sufficiently high accuracy of the simulated aerial images.

The simulated aerial image of the design of the photolithography mask can be used in different ways. Instead of acquiring an aerial image of the photolithography mask, a simulation of the aerial image of a design of the photolithography mask using a method according to the first embodiment of the disclosure is used, thereby considerably reducing the computation time and increasing the accuracy of the simulated aerial image.

In an example, based on a simulated aerial image the design of the corresponding photolithography mask is improved and mask 3D effects are mitigated without having to print a wafer, e.g., by modifying the design layout of the photolithography mask, by modifying the material structure thickness within a grating of the photolithography mask, or by applying optical proximity correction techniques to the photolithography mask, for example by adding sub resolution assist features, etc.

In an example, the simulated aerial image is used for defect detection. Given an acquired aerial image of a photolithography mask, the photolithography mask is checked for defects by simulating an aerial image of a design of the photolithography mask and by comparing the acquired aerial image to the simulated aerial image.

A method for detecting defects in a photolithography mask according to a second embodiment of the disclosure comprises: acquiring an aerial image of the photolithography mask using an aerial image acquisition system; simulating an aerial image of a design of the photolithography mask using a computer implemented method according to the first embodiment of the disclosure; and detecting defects in the photolithography mask by comparing the acquired aerial image to the simulated aerial image. In this way, simulated aerial images can be used to detect defects in a photolithography mask with high accuracy and at low computation times. This allows to improve the design of the photolithography mask without involving the actual printing of a wafer. The detected defects can be used for the purpose of repairing the photolithography mask.

An aerial image acquisition system refers to a system that can be used to acquire an aerial image of a photolithography mask, for example an inspection system such as an optical photolithography mask metrology or qualification system. An aerial image acquisition system can, for example, be configured as shown in FIG. 1 or FIG. 2, with the difference that the wafer is replaced by a camera sensor.

In an example, the relevance of defects in an acquired charged particle beam image of a photolithography mask is assessed by simulating an aerial image using the acquired charged particle beam image of the photolithography mask as a design of the photolithography mask and by comparing the defects in the charged particle beam image to the corresponding locations in the simulated aerial image. If a defect is present in the aerial image and may cause a failure, the defect is assessed as relevant. If a defect is not present in the aerial image or unproblematic, the defect is assessed as irrelevant. This can save a lot of time and resources, since no rigorously simulated aerial image of the photolithography mask is involved and since the design of the photolithography mask is only modified in case of relevant defects.

A method for assessing the relevance of defects in a photolithography mask according to a third embodiment of the disclosure comprises: acquiring a charged particle beam image of the photolithography mask comprising one or more defects using a charged particle beam image acquisition system; simulating an aerial image of a design of the photolithography mask using a computer implemented method according to the first embodiment of the disclosure, wherein the charged particle beam image is used as a design of the photolithography mask; and assessing the relevance of the one or more defects in the photolithography mask using the simulated aerial image. The simulated aerial image can be compared to the charged particle beam image or to a reference image, e.g., an acquired or simulated aerial image to assess the relevance of defects. In addition or alternatively, the critical dimension (CD) of the simulated aerial image can be used to assess the relevance of defects. For example, locations where the CD lies below a predefined threshold can be marked as relevant defects. A CD of a device can be defined as the smallest width of a structure such as a line or hole, or the smallest space between two structures such as two lines or holes. Thus, the CD regulates the overall size and density of the designed device. Using a method according to the third embodiment of the disclosure, the relevance of defects can be assessed accurately and at low computation times due to an accurate and fast simulation of the aerial image. The defects assessed as relevant can be used for the purpose of repairing the relevant defects in the photolithography mask.

In an example, a method for manufacturing a photolithography mask comprises simulating an aerial image of a design of a photolithography mask in a photolithography system using a computer implemented method using a computer implemented method according to the first embodiment of the disclosure, detecting defects in the design of the photolithography mask, improving the design of the photolithography mask, and manufacturing the photolithography mask using the improved design. The defects in the aerial image can be detected using methods known to a person skilled in the art, e.g., by analyzing the critical distance of the structures in the aerial image or by comparing the structures with a model.

In an example, an acquired aerial image of a photolithography mask is aligned to a simulated aerial image of a design of the photolithography mask. The shift or displacement field between both images can, for example, be used in the photolithography process in order to improve the alignment of subsequently printed layers of a wafer.

A method for aligning an aerial image of a photolithography mask with a design of the photolithography mask according to a fourth embodiment of the disclosure comprises: acquiring an aerial image of the photolithography mask using an aerial image acquisition system; simulating an aerial image of the design of the photolithography mask using a computer implemented method according to the first embodiment of the disclosure; and aligning the acquired aerial image to the simulated aerial image via image registration. The alignment of an aerial image of a photolithography mask with a design of the photolithography mask can be used during wafer printing, in particular for the purpose of preventing alignment defects.

In an example, training data for training a machine learning model can be generated by simulating a number of aerial images for designs of photolithography masks. The designs of photolithography masks can be defect-free or contain defects. The training data can be used to train a machine learning model, e.g., for defect detection, assessment of the relevance of defects or for aerial image alignment. Since the machine learning model directly learns from the training data the tasks can be performed with high accuracy.

A computer implemented method for generating training data for training a machine learning model according to a fifth embodiment of the disclosure comprises: obtaining multiple designs of photolithography masks; and for each obtained design, simulating an aerial image of the obtained design using a computer implemented method according to the first embodiment of the disclosure and adding the simulated aerial image to the training data.

In an example, the simulated aerial image is used to generate a digital twin of a machine, which uses acquired aerial images of photolithography masks. The digital twin of the machine is a digital simulation of the machine, which uses a method for simulating an aerial image of a design of a photolithography mask according to the first embodiment of the disclosure to simulate the acquisition of an aerial image within the machine. The digital twin of the machine can be used for many different purposes, e.g., for specifying the functionality and the desired properties of the machine, for presenting the functionality of the machine to the customer before the machine is built or delivered, or for accelerating the development of parts of the machine, for example of the user interface, etc.

A non-transitory computer-readable medium according to a sixth embodiment of the disclosure comprises a stored computer program executable by a computing device, the computer program comprising code for executing a method according to the first embodiment of the disclosure.

A computer program product according to a seventh embodiment of the disclosure comprises instructions which, when the program is executed by a computer, cause the computer to carry out a method according to the first embodiment of the disclosure.

A system for simulating an aerial image of a design of a photolithography mask according to an eighth embodiment of the disclosure comprises a data analysis device comprising at least one memory and at least one processor configured to perform the steps of a computer implemented method according to the first embodiment of the disclosure. The system can optionally comprise a database for saving and/or loading selected illumination angles for illumination angle distributions for illumination pupils. Thus, the selected illumination angles can be used repeatedly.

A system for detecting defects in a photolithography mask according to a ninth embodiment of the disclosure comprises a subsystem for obtaining an aerial image of the photolithography mask and a data analysis device comprising at least one memory and at least one processor configured to perform the steps of a method according to the second embodiment of the disclosure.

A system for assessing the relevance of defects in a photolithography mask according to a tenth embodiment of the disclosure comprises a subsystem for obtaining a charged particle beam image of the photolithography mask and a data analysis device comprising at least one memory and at least one processor configured to perform the steps of a method according to the third embodiment of the disclosure.

A system for aligning an aerial image of a photolithography mask with a design of the photolithography mask according to an eleventh embodiment of the disclosure comprises a subsystem for obtaining an aerial image of the photolithography mask and a data analysis device comprising at least one memory and at least one processor configured to perform the steps of a method according to the fourth embodiment of the disclosure.

The disclosure described by examples and embodiments is not limited to the embodiments and examples but can be implemented by those skilled in the art by various combinations or modifications thereof.

### BRIEF DESCRIPTION OF THE DRAWINGS

FIG. 1 illustrates an exemplary transmission-based photolithography system, e.g., a deep ultraviolet (DUV) photolithography system;

FIG. 2 illustrates an exemplary reflection-based photolithography system, e.g., an extreme ultraviolet (EUV) photolithography system;

FIG. 3 shows a flowchart of a computer implemented method for simulating an aerial image of a design of a photolithography mask in a photolithography system according to the first embodiment of the disclosure;

FIG. 4 shows an intensity distribution over different illumination angles for an illumination pupil and an imaging pupil in an illumination pupil plane;

FIG. 5A shows a magnified view of the illumination pupil in FIG. 4 with equidistant selected illumination angles and a corresponding partitioning of the illumination angle distribution into segments;

FIG. 5B shows a magnified view of the illumination pupil in FIG. 4 with a selection of illumination angles obtained by solving an optimization problem and a corresponding partitioning of the illumination angle distribution into segments;

FIG. 6 shows selected illumination angles and corresponding segments for different illumination angle distributions;

FIG. 7 illustrates the accuracy of the computer implemented method for simulating an aerial image of a photolithography mask;

FIG. 8 shows a comparison of different error metrics for a simulated aerial image using equidistant selected illumination angles and for a simulated aerial image using optimized selected illumination angles;

FIG. 9 shows a flowchart of a method for detecting defects in a photolithography mask according to the second embodiment of the disclosure;

FIG. 10 shows a flowchart of a method for assessing the relevance of defects in a photolithography mask according to a third embodiment of the disclosure;

FIG. 11 shows a flowchart of a method for aligning an aerial image of a photolithography mask with a design of the photolithography mask according to a fourth embodiment of the disclosure;

FIG. 12 illustrates a flowchart of a computer implemented method for generating training data for training a machine learning model;

FIG. 13 illustrates a system for detecting defects in a photolithography mask according to a ninth embodiment of the disclosure;

FIG. 14 illustrates a system for assessing the relevance of defects in a photolithography mask according to a tenth embodiment of the disclosure; and

FIG. 15 illustrates a system for aligning an aerial image of a photolithography mask with a design of the photolithography mask according to an eleventh embodiment of the disclosure.

### DETAILED DESCRIPTION

In the following, advantageous exemplary embodiments of the disclosure are described and schematically shown in the figures. Throughout the figures and the description, same reference numbers are used to describe same features or components. Dashed lines indicate optional features.

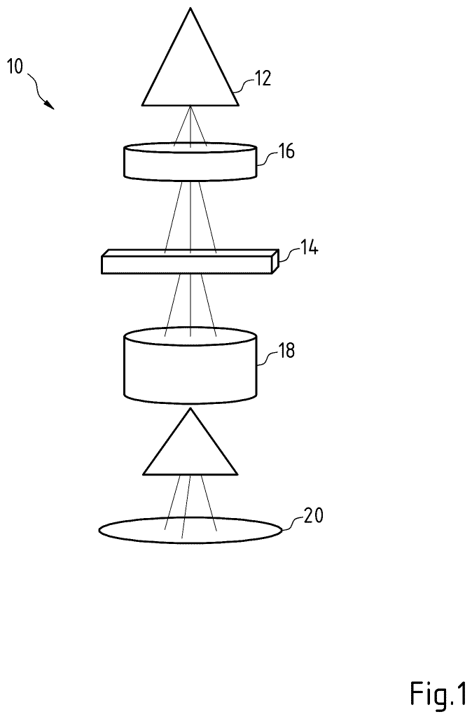

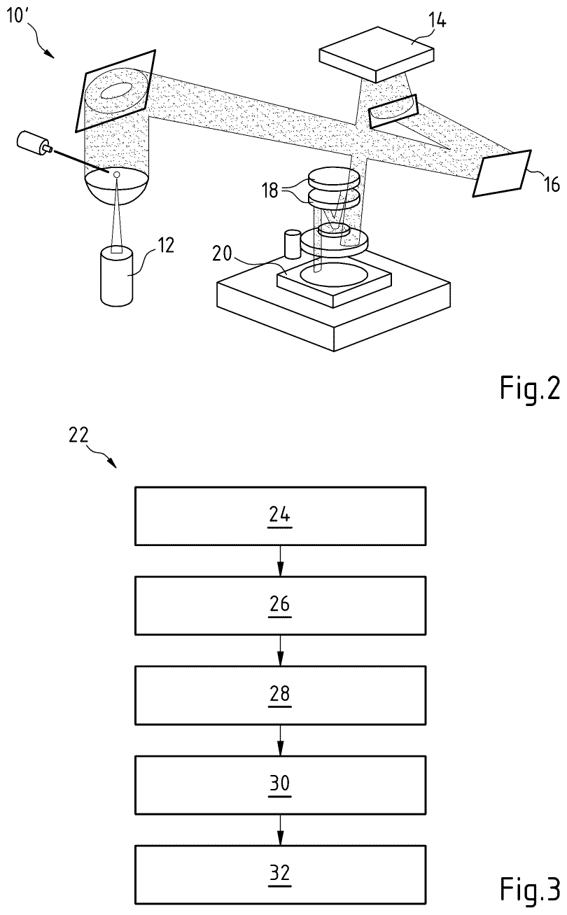

The methods described herein can be used with transmission-based photolithography systems 10 or reflection-based photolithography systems 10′ as shown in FIGS. 1 and 2.

FIG. 1 illustrates an exemplary transmission-based photolithography system 10, e.g., a DUV photolithography system. Major components are a light source 12, which may be a deep-ultraviolet (DUV) excimer laser source, imaging optics which, for example, define the partial coherence and which may include optics that shape radiation from the light source 12, a photolithography mask 14, illumination optics 16 that illuminate the photolithography mask 14 and projection optics 18 that project an image of the photolithography mask pattern onto a photoresist layer of a wafer in a wafer plane 20. An adjustable filter or aperture at the pupil plane of the projection optics 18 may restrict the range of beam angles that impinge on the wafer plane 20, where the largest possible angle γₘₐₓ defines the numerical aperture (NA) of the projection optics

NA=n sin(γₘₐₓ)

wherein n is the refractive index of the media between the substrate and the last element of the projection optics 18, e.g., n=1 in case of vacuum.

In the present document, the terms “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g. having a wavelength in the range of about 3-100 nm).

Illumination optics 16 may include optical components for shaping, adjusting and/or projecting radiation from the light source 12 before the radiation passes the photolithography mask 14. Projection optics 18 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 18 may comprise various types of optical systems, including refractive optics, reflective optics, apertures and catadioptric optics, for example. Illumination optics 16 and projection optics 18 may also include components operating according to any of these design types for directing, shaping or controlling the projection beam of radiation, collectively or singularly.

FIG. 2 illustrates an exemplary reflection-based photolithography system 10′, e.g., an extreme ultraviolet light (EUV) photolithography system 10′. Major components are a light source 12, which may be a laser plasma light source, illumination optics 16 which, for example, define the partial coherence and which may include optics that shape radiation from the light source 12, a photolithography mask 14, and projection optics 18 that project an image of the photolithography mask pattern onto a photoresist layer of a wafer. An adjustable filter or aperture at the pupil plane of the projection optics 18 may restrict the range of beam angles that impinge on the wafer plane 20, where the largest possible angle γₘₐₓ defines the numerical aperture as described above.

For reflection-based photolithography systems 10′, but also for transmission-based photolithography systems 10, the increasing structure size in vertical dimension with respect to the lateral dimension is no longer negligible compared to the wavelength. Thus, approximation methods such as the Kirchhoff or thin element approach do not yield approximations of near fields or aerial images of sufficient accuracy. Thus, rigorous simulations of electromagnetic near fields are used. In addition, for 3D masks the illumination angle cannot be assumed as constant anymore, thus involving rigorous simulations of electromagnetic near fields for each illumination angle. Such rigorous simulations for each illumination angle are computationally highly expensive. Therefore, approximations are involved.

The Hopkins approach assumes that a change in the illumination angle only results in a frequency shift of the respective diffraction spectrum of the photolithography mask. However, this approach does not hold for 3D masks. The local Hopkins approach is a compromise between accuracy and computational speed. It is based on partitioning the illumination pupil into a number of segments, for which the illumination angle is assumed constant. Thus, locally within each segment the Hopkins approach is applied. Due to the limited size of the segments the approximation error is limited.

However, the local Hopkins approach involves partitioning the illumination angle distribution in the pupil plane into multiple segments and selecting an illumination angle from each of the segments. This procedure involves user effort and can lead to suboptimal aerial image simulations.

In order to increase the accuracy of the simulated aerial image, according to a first embodiment of the disclosure illustrated by the flowchart in FIG. 3, the computer implemented method 22 for simulating an aerial image of a design of a photolithography mask 14 in a photolithography system 10, 10′, the photolithography mask 14 being illuminated by an illuminating optical unit by using a light source 12 emitting illuminating radiation, the illuminating optical unit having a pupil plane, comprises: obtaining an illumination angle distribution in the pupil plane of the light source in an illumination distribution step 24; selecting a number of illumination angles from the illumination angle distribution by solving an optimization problem in an optimization step 26; for each selected illumination angle, simulating an electromagnetic near field of the design of the photolithography mask illuminated by incident electromagnetic waves of the selected illumination angle in a near field plane in a near field simulation step 28; for at least one further illumination angle of the illumination angle distribution in the pupil plane of the light source 12, which was not selected, approximating an electromagnetic near field of the design of the photolithography mask illuminated by incident electromagnetic waves of the respective illumination angle using the simulated electromagnetic near fields for the selected illumination angles in a near field approximation step 30; and obtaining the simulated aerial image 48 of the design of the photolithography mask 14 by superimposing the intensities obtained by imaging the simulated electromagnetic near fields and the at least one approximated electromagnetic near field into a wafer plane 20 in an aerial image simulation step 32.

An electromagnetic near field of the design of the photolithography mask illuminated by incident electromagnetic waves of the selected illumination angle can be simulated in a near field plane in the near field simulation step 28, for example, by using rigorous simulation methods for electromagnetic near fields such as FDTD or RWCA or by using approximation methods such as the one disclosed in PCT/EP2023/087651 or DE 10 2022 135 019.3.

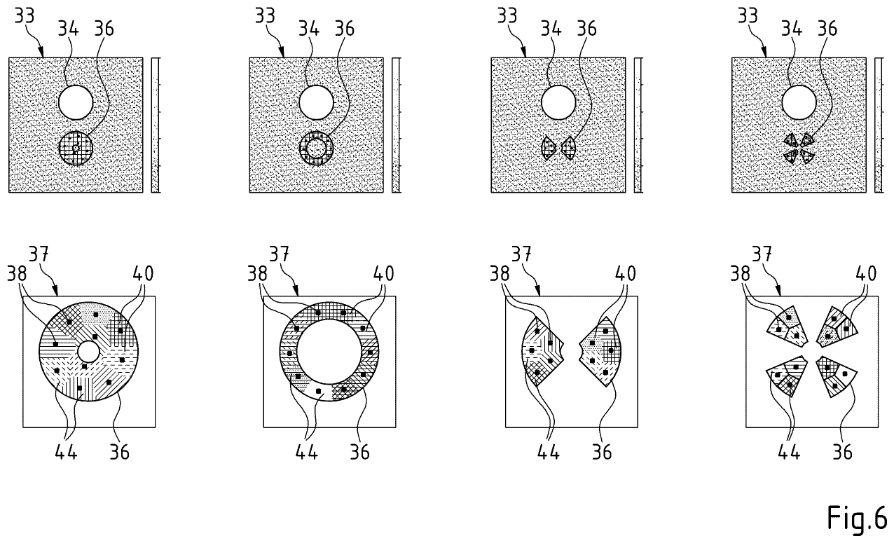

An illumination angle distribution in the pupil plane of the light source can be obtained in different ways. For example, by an equidistant sampling of the illumination pupil plane and using all respective illumination angles inside the illumination pupil. In particular, the equidistant sampling of the pupil plane could be chosen such that all angles correspond to the plane waves which fulfill periodic boundary conditions for the simulated design and electric field. In another example, the illumination angle distribution could be obtained by randomly sampling the pupil plane and using all respective illumination angles inside the illumination pupil. In another example, the illumination angle distribution could be obtained by using a tessellation method, e.g. a triangulation, of the illumination pupil and using all nodes as illumination angles. Standard illumination angle distributions are, for example, shown in FIG. 6.

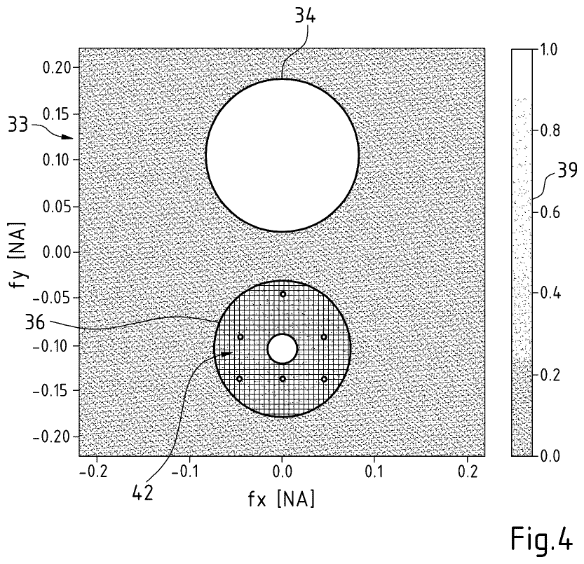

FIG. 4 shows an intensity distribution over different illumination angles for an illumination pupil 36 and an imaging pupil 34 in an illumination pupil plane 33. The illumination angles are indicated in the illumination pupil plane 33 by the numerical aperture of their horizontal and vertical components on the horizontal and vertical axis, respectively.

For each illumination angle a specific illumination intensity can be indicated as shown by the illumination intensity scale 39 in FIG. 4. The illumination intensity can be taken into account by the computer implemented method 22 for simulating an aerial image of a photolithography mask 14.

According to an example of the first embodiment of the disclosure, the illumination angle distribution is subsampled to generate a grid 42 of a discrete set of illumination angles corresponding to electromagnetic plane waves which fulfill periodic boundary conditions in the near field plane (on the considered computational domain or field of view). The generated grid 42 can be a regular grid 42 as shown in FIG. 4. Alternatively, the generated grid 42 can be irregular. For example, the distribution of grid points can correlate with the intensity of the illuminating radiation for the different illumination angles, e.g., in regions of the illumination pupil 36 with higher illumination intensity the density of the grid points can be increased, whereas in regions with lower illumination intensity the density of the grid points can be decreased. The density of the grid points can be increased near the boundary of the illumination pupil in order to reduce approximation errors in case of an extrapolation of mask spectra.

Electromagnetic near fields of the design of the photolithography mask can be approximated in different ways.

According to an example of the first embodiment of the disclosure, approximating an electromagnetic near field of the design of the photolithography mask 14 for a further illumination angle 40, which was not selected, comprises shifting the mask spectrum of the simulated electromagnetic near field of the closest selected illumination angle 38, for example according to the local Hopkins approach described above.

According to an example of the first embodiment of the disclosure, approximating an electromagnetic near field of the design of the photolithography mask 14 for a further illumination angle 40, which was not selected, comprises interpolation or regression of mask spectra of simulated electromagnetic near fields. The mask spectra of the simulated electromagnetic near fields for the selected illumination angles 38 can, thus, be used to approximate the mask spectra of the further illumination angles 40, which were not selected.

Various interpolation methods are known to the person skilled in the art. For example, linear, quadratic or higher order interpolation methods. Another example is inverse distance weighted interpolation. To approximate a mask spectrum for a further illumination angle 40, which was not selected, inverse distance weighted interpolation uses the mask spectra of the simulated electromagnetic near fields for the selected illumination angles 38. The weights assigned to the mask spectra of the simulated electromagnetic near fields for the selected illumination angles 38 are proportional to their inverse distance to the illumination angle that was not selected in the illumination pupil 36. Thus, the weights diminish as a function of the distance in the pupil plane 33. The function of the distance can be raised to the power of a value p∈ [symbol] .

Alternatively, radial basis function (RBF) interpolation can be used. RBF interpolation is an advanced method in approximation theory for constructing high-order accurate interpolants of unstructured data, possibly in high-dimensional spaces. The interpolant takes the form of a weighted sum of radial basis functions, like for example Gaussian distributions. RBF interpolation is often spectrally accurate and, thus, well suited for interpolating mask spectra.

Alternatively, Delauney triangulation can be used with subsequent linear interpolation. A Delaunay triangulation for a given set of selected illumination angles 38 is a triangulation such that no selected illumination angle 38 lies inside the circumcircle of any triangle. Given a Delauney triangulation of the selected illumination angles 38, mask spectra of further illumination angles 40, which were not selected, can be computed by linearly interpolating between the three mask spectra of the simulated electromagnetic near fields of the selected illumination angles 38 that belong to the same Delaunay triangle. In case that further illumination angles 40 do not lie inside any of the Delaunay triangles, extrapolation between the mask spectra of the simulated electromagnetic near fields of the closest selected illumination angles 38 can be used.

Further interpolation methods such as splines, in particular B-splines, can be used for interpolating between mask spectra of simulated electromagnetic near fields of selected illumination angles 38.

Instead of interpolating between mask spectra of simulated electromagnetic near fields of selected illumination angles 38, regression approaches can be used to approximate mask spectra of electromagnetic near fields of further illumination angles 40, which were not selected. For example, polynomial regression, splines, in particular B-splines, or Bézier curves can be used for regression. They can, for example, be optimized using least squares methods.

The selection of illumination angles for simulating an electromagnetic near field of a photolithography mask 14 is relevant for the accuracy and the computation time of the computer implemented method 22 for the simulation of an aerial image.

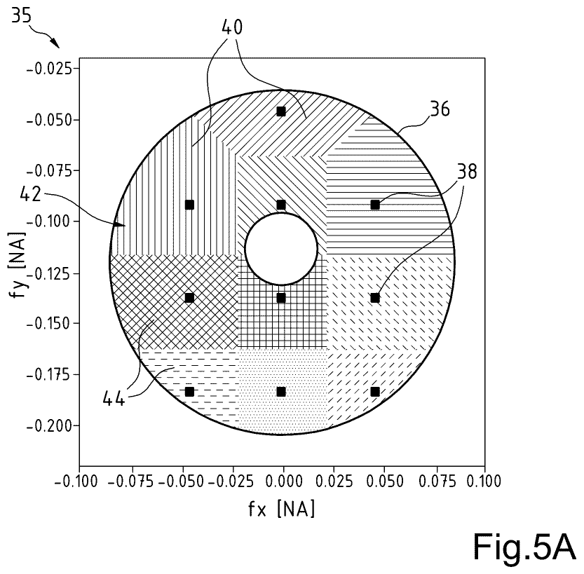

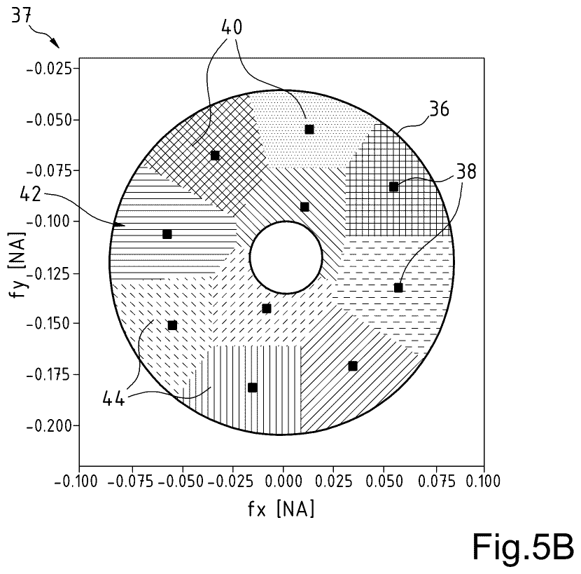

FIG. 5A shows a magnified view of the illumination pupil 36 in FIG. 4 with equidistant selected illumination angles 35 and a corresponding partitioning of the illumination angle distribution into segments 44. Each illumination angle is, thereby, assigned to the closest selected illumination angle 38. This selection of illumination angles is done by hand, which is tedious for the user, and suboptimal since the selected illumination angles 38 are not optimized with respect to the approximation error of the local Hopkins approach.

FIG. 5B shows a magnified view of the illumination pupil 36 in FIG. 4 with optimized selected illumination angles 37 obtained by solving an optimization problem, and a corresponding partitioning of the illumination angle distribution into segments 44. The optimization problem is solved automatically by the computer implemented method 22, thus yielding selected illumination angles 38, which are optimal with respect to some optimality criterion, and without requiring any user effort. The computer implemented method can be used for optimizing the selected illumination angles 38 for any shape of the illumination pupil 36 (e.g., annular, dipole, quadrupole, free-form) and, optionally, for any illumination intensity distribution.

The optimization problem can comprise various optimality criteria, e.g., in an objective function, and can be optimized in various ways.

The number of selected illumination angles can be determined in different ways. The number can be selected by a user. The number can be selected by solving the optimization problem several times for different numbers of selected illumination angles. Heuristics can also be used to select the number. The number can also be a parameter in the optimization problem that is optimized by solving the optimization problem. The number of illumination angles can also be determined with respect to computational limitations of the computing system.

In an example of the first embodiment of the disclosure, the optimization problem comprises optimizing an objective function containing an approximation error. An approximation error refers to a deviation between one or more values and one or more target values.

According to an example of the first embodiment of the disclosure, the optimization problem comprises optimizing an objective function containing a measurement related to the approximation error of the simulated aerial image. The measurement can, e.g., comprise the approximation error of the simulated aerial image and some reference image, or it can comprise some other measurement, which is indirectly related to the approximation error, for example the maximum deviation of the further illumination angles 40 from the respectively closest selected illumination angle 38.

According to an example of the first embodiment of the disclosure, the optimization problem comprises optimizing an objective function containing the number of selected illumination angles 38.

The objective function can be a weighted sum of two or more terms representing different optimization criteria. For example, the objective function can comprise a term measuring the approximation error of the simulated aerial image and a term measuring the number of selected illumination angles. By minimizing this objective function, a compromise between accuracy and computation time can be achieved. The objective function can, for example, be optimized using Lagrange multipliers.

According to an example of the first embodiment of the disclosure, the optimization problem comprises a deviation of one or more closest selected illumination angles from one or more further illumination angles 40 in the illumination pupil 36. By minimizing the deviation of further illumination angles 40 from the closest selected illumination angles 38, the error due to the local Hopkins approximation is reduced. For example, the maximum deviation of any further illumination angle 40 for the respectively closest selected illumination angle 38 can be minimized. Segments 44 of illumination angles associated with a selected illumination angle 38 can be obtained by generating a Delaunay triangulation of the selected illumination angles 38 and computing the dual graph, i.e., the Voronoi regions, by connecting the centers of the circumcircles of the Delaunay triangles. The generated Voronoi regions then correspond to the segments 44.

The deviation, difference or distance between two illumination angles a and b can be measured in different ways. For example, the deviation, difference or distance between a and b can be measured by the norm of the difference of the angles a and b

$$d ( a , b ) = ‖ ( \begin{matrix}{a}_{x} - {b}_{x} \\ {a}_{y} - {b}_{y}\end{matrix} ) ‖ ,$$

wherein the angles a and b can, for example, be defined by their numerical aperture (coordinate on the corresponding pupil grid) or in the unit degree or radians.

According to an example of the first embodiment of the disclosure, the optimization problem comprises clustering illumination angles of the illumination angle distribution in the pupil plane 33. The clusters then correspond to the segments 44, and specific points of the clusters, e.g., the cluster centroids, correspond to the selected illumination angles 38. For each cluster, a single illumination angle can be selected. Alternatively, more than one illumination angle can be selected for each cluster.

In an example, k-means clustering is used, which minimizes the total squared error of the further illumination angles 40 aᵢ from a selected illumination angle 38 μⱼ within each segment 44 Rⱼ

$${min}_{{μ}_{j}} {\sum }_{j = 1}^{N} {\sum }_{i ∈ {R}_{j}} {‖ {a}_{i} - {μ}_{j} ‖}^{2} {w}_{i} . \qquad ( 1 )$$

A segment Rⱼ corresponding to a selected illumination angle μⱼ contains all further illumination angles 40 that deviate less from the selected illumination angle μⱼ than from the other selected illumination angles 38. The deviation can, for example, refer to a difference in the angle or to a distance in the illumination pupil plane. The number N of selected illumination angles 38 can be selected by a user, or it can be heuristically computed, e.g., using the Elbow method, etc. The result is shown in FIG. 5B. Since the distances between the further illumination angles 40 and the selected illumination angles 38 are minimized, the approximation error of the local Hopkins approach is minimized for the number N of segments 44. In an example, the distances are weighted by weights wᵢ, e.g., by the illumination intensities of the illumination angles aᵢ. Alternatively, an irregular grid can be used, whose density of grid points corresponds to the illumination intensity of the illumination angle distribution.

FIG. 6 shows selected illumination angles 38 and corresponding segments 44 for different illumination pupils 36, i.e., an annular illumination pupil, a dipole illumination pupil and a quadrupole illumination pupil. The computer implemented method 22 can be applied to any other type of illumination pupil 36 as well. The selected illumination angles 38 are obtained by solving an optimization problem comprising k-means clustering.

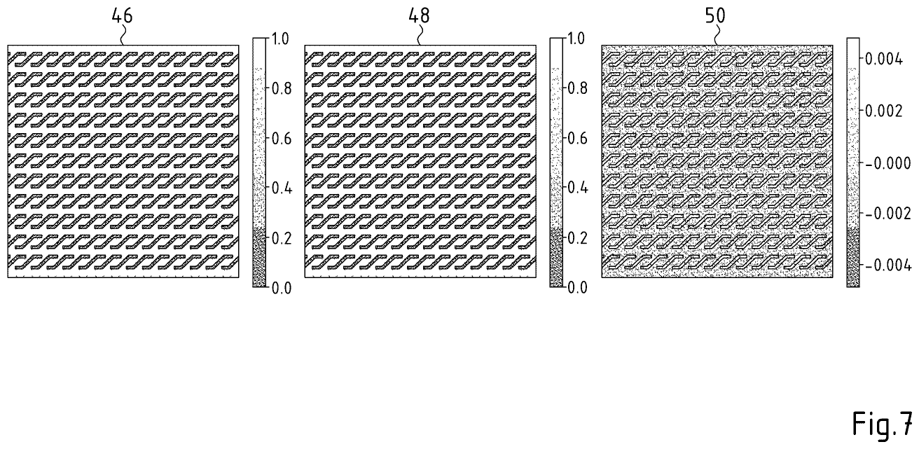

FIG. 7 illustrates the accuracy of the computer implemented method 22 for simulating an aerial image of a photolithography mask 14. On the left-hand side, a reference aerial image 46 is shown. The reference aerial image 46 is obtained according to the Abbe approach by simulating electromagnetic near fields for each of the 3248 illumination angles in an annular illumination pupil 36 shown on the left in FIG. 6 using the method disclosed in PCT/EP2023/087651 or DE 10 2022 135 019.3, and by superimposing the intensities obtained by imaging the simulated electromagnetic near fields into a wafer plane 20. The field of view is 375×375 pixels with a pixel size of 16 nm, which corresponds to 6 m×6 m on the photolithography mask. The computation time is approximately 167 seconds. In the center of FIG. 7, a simulated aerial image 48 is shown, which is obtained using the local Hopkins approach by simulating an electromagnetic near field only for 10 selected illumination angles of the 3248 illumination angles using the method disclosed in PCT/EP2023/087651 or DE 10 2022 135 019.3, wherein the 10 selected illumination angles are selected by k-means clustering. The computation time is approximately 0.5 seconds. Thus, the speedup is about a factor of 334. The right-hand side of FIG. 7 shows the difference image 50 indicating the difference between the reference aerial image 46 and the simulated aerial image 48. The absolute deviations are below 0.004. Thus, already 0.3% of the illumination angles are sufficient to obtain highly accurate simulated aerial images if the illumination angles are selected by k-means clustering.

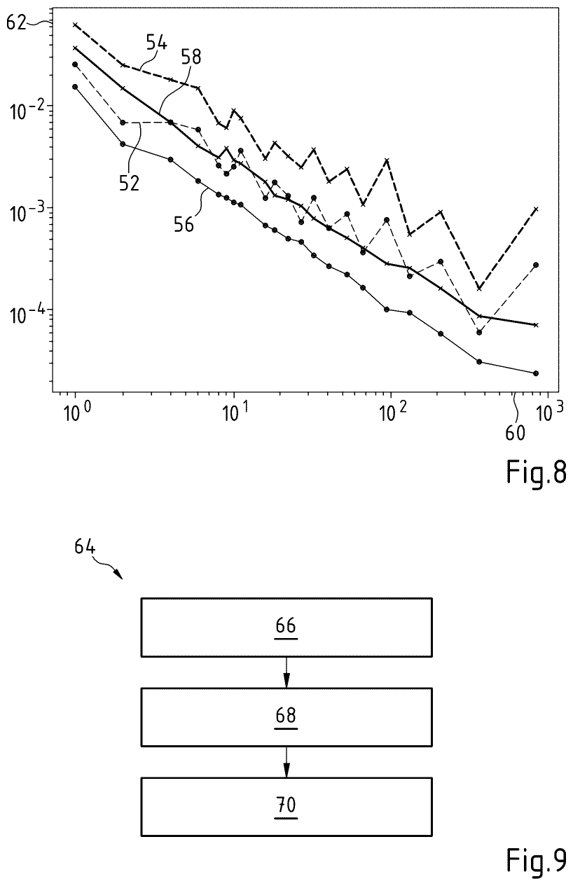

FIG. 8 shows a comparison of different error metrics for a simulated aerial image using equidistant selected illumination angles 35 and for a simulated aerial image using optimized selected illumination angles 37 using k-means clustering in an annular illumination pupil 36 shown on the left in FIG. 6. On the horizontal axis 60 the number of selected illumination angles 38 is indicated. On the vertical axis 62 the values of the different error metrics are indicated. For equidistant selected illumination angles 35 the root mean squared error 52 and the maximum error 54 of the aerial image intensities is shown. For optimized selected illumination angles 37 the root mean squared error 56 and the maximum error 58 of the aerial image intensities is shown. The plots illustrate that with an increasing number of selected illumination angles 38 the error metrics decrease.

For optimized selected illumination angles 37 the error metrics 56, 58 are always lower than the corresponding error metrics 52, 54 for equidistant selected illumination angles 35. In addition, the error metrics for optimized selected illumination angles 37 are monotonously decreasing, whereas the error metrics for equidistant selected illumination angles 35 do not decrease monotonously. Instead, they show an unpredictable behavior and can even increase for a larger number of clusters.

Apart from k-means clustering, there are various other ways for optimizing the selected illumination angles 38.

In an example, mean-shift clustering is used. Let

$$f ( x ) = \frac{1}{{nh}^{d}} {\sum }_{i = 1}^{n} K ( \frac{x - {a}_{i}}{h} ) {w}_{i}$$

indicate the Parzen density estimator over the illumination pupil 36, wherein K is a kernel function, e.g., a Gaussian, n is the number of illumination angles in the d-dimensional pupil plane and h is a bandwidth parameter. In an example, the kernels are weighted by weights wᵢ, e.g., depending on the illumination intensities of the illumination angles aᵢ. In another example, an irregular grid is used, whose density of grid points corresponds to the illumination intensity of the illumination angle distribution. The Parzen density estimator is a non-parametric estimator for a probability density function representing the illumination angle distribution. A clustering of the illumination angles is obtained by finding the modes of this probability density function using the derivative of the Parzen density estimator

$$F ( x ) = \frac{1}{{nh}^{d}} {\sum }_{i = 1}^{N} ∇ K ( \frac{x - {a}_{i}}{h} ) {w}_{i} . \qquad ( 2 )$$

In another example, the expectation maximization (EM) algorithm is used for clustering. The EM algorithm is an iterative algorithm used to find local maximum likelihood parameters of a statistical model. Typically, these models involve latent variables in addition to unknown parameters and known data observations. For example, a Gaussian mixture model can be optimized in this way, wherein the latent variables indicate the Gaussian mixture component from which each observation originates.

In an example, an unsupervised machine learning algorithm is used for clustering, e.g., a self-organizing map or a neural gas. When a training example is fed to the network, its Euclidean distance to the weight vectors of all neurons of the self-organizing map or the neural gas is computed. The weight vectors of the neurons are adapted inversely to the distance of each neuron to the training example. Self-organizing maps differ from a neural gas in that the topology of the neurons is fixed and distance is measured within the map.

In an example, the optimization problem comprises a hierarchical clustering of the illumination angles of the illumination angle distribution in the pupil plane. Using a hierarchical clustering method, a cluster tree can be obtained.

The root cluster of the cluster tree is a cluster that has no parent. A leaf cluster of the cluster tree is a cluster that has no child clusters. An internal cluster of the cluster tree is a cluster that has one or more child clusters. The root cluster is part of the internal clusters. Each cluster of the cluster tree comprises a set of illumination angles.

In the cluster tree, the root cluster contains all illumination angles, each leaf cluster contains a single illumination angle and for all internal clusters of the cluster tree the following applies: for an internal cluster with n child clusters let aᵢ, i∈{1, . . . , n} indicate the set of illumination angles of child cluster I, then {a₁, . . . , aₙ} is a partition of the set of illumination angles contained in the internal cluster. This means, that each illumination angle of a parent cluster is assigned to exactly one of the child clusters. The tree level of a cluster is the number of edges along the unique path between the cluster and the root cluster.

The hierarchical cluster tree can, for example, be built using an agglomerative clustering method or using a divisive clustering method. In an agglomerative clustering method two clusters are merged, starting from the leaves of the cluster tree, based on a cluster distance measure. The lower the cluster distance measure for two clusters, the earlier the two clusters will be merged. In a divisive clustering method, a cluster is iteratively split, starting from the root cluster of the cluster tree, based on the dissimilarity of illumination angles within each cluster.

The cluster distance measure indicates the distance between two clusters each containing a set of illumination angles. The cluster distance measure can comprise a function of pairwise differences d(a,b), each between an illumination angle a of the first cluster A and an illumination angle b of the second cluster B.

The pairwise differences d(a,b) can be weighted by the illumination intensity of a and b, e.g., by maximum illumination intensity. In this way, clusters with lower illumination intensity will be merged earlier leading to larger clusters within segments of lower intensity and smaller clusters within segments of higher intensity. The pairwise differences d(a,b) can, alternatively, be weighted by difference of the illumination intensity. In this way, clusters with similar illumination intensities will be merged earlier. The cluster distance measure can also comprise the computation of centroids. Cluster centroids can, for example, be weighted with an average illumination intensity of the cluster wa, wb. Otherwise, if no weighting shall be used, the weights w_{ab}, w_{ā}, w_{b̅} can be set to 1.

Let A and B be two clusters of the cluster tree. Then the cluster distance measure CD between cluster A and B can, for example, be measured in the following ways:

$$\begin{matrix}CD ( A , B ) = min \{ d ( a , b ) {w}_{ab} \vert a ∈ A , b ∈ B \} & Minimal differecnce of all weighted illumination \\ & angle pairs from both clusters \\ CD ( A , B ) = max \{ d ( a , b ) {w}_{ab} \vert a ∈ A , b ∈ B \} & Maximal differecnce of all weighted illumination \\ & angle pairs from both clusters \\ CD ( A , B ) = mean \{ d ( a , b ) {w}_{ab} \vert a ∈ A , b ∈ B \} & Average differecnce of all weighted illumination \\ & angle pairs from both clusters \\ CD ( A , B ) = median \{ d ( a , b ) {w}_{ab} \vert a ∈ A , b ∈ B \} & Median differecnce of all weighted illumination \\ & angle pairs from both clusters \\ CD ( A , B ) = d ( {w}_{\overline{a}} \overline{a} , {w}_{\overline{b}} \overline{b} ) & Distance of centroids \overline{a} , \overline{b} of the clusters , which \\ & can be weighted \\ CD ( A , B ) = \frac{d {( {w}_{\overline{a}} \overline{a} , {w}_{\overline{b}} \overline{b} )}^{2}}{\frac{1}{\vert A \vert} + \frac{1}{\vert B \vert}} & \begin{matrix}\text{Ward’s} minimum variance method , where \overline{a} , \overline{b} \\ are the centroids of the clusters , which can be \\ weighted\end{matrix}\end{matrix}$$

Ward's minimum variance method measures the increase in variance when two clusters are joined. The lower the increase in variance is, the lower is the cluster distance and the earlier the clusters will be merged by the hierarchical clustering algorithm. Other cluster distance measures can be used as well.

A hierarchical clustering is advantageous, since it allows for an easy adaptation of the number of clusters, and, thus, of the number of selected illumination angles 38. The selected illumination angles 38 correspond to specific points of the clusters, e.g., the cluster centroids. Each level of the cluster tree corresponds to a clustering comprising a specific number of clusters and, thus, to a specific number of selected illumination angles 38. To increase the number of selected illumination angles 38, the clustering on the next higher tree level can be used to define the selected illumination angles 38. To decrease the number of selected illumination angles 38, the clustering on the next lower tree level can be used to define the selected illumination angles 38. For each cluster an illumination angle is selected, e.g., the centroid of the cluster. A user interface can be configured to let the user browse through the tree levels to select a suitable clustering and selected illumination angles 38.

According to an example of the first embodiment of the disclosure, the optimization problem comprises a deviation of the obtained simulated aerial image 48 and a reference aerial image 46. A reference aerial image 46 can, for example, be obtained by using rigorous simulation methods for all illumination angles according to the Abbe method. Alternatively, a reference aerial image 46 can be obtained by using a local Hopkins approach with a number of segments 44 that is larger than the number of selected illumination angles 38. The deviation of the obtained aerial image 48 from the reference aerial Image 46 can, for example, be measured by the root mean squared error of the intensities or by the maximum intensity error. The deviation of the obtained aerial image 48 from the reference aerial image 46 can be minimized.

In order to optimize the number of selected illumination angles 38, a threshold can be specified and the number of selected illumination angles 38 can be increased until the deviation of the obtained simulated aerial image 48 from the reference aerial image 46 lies below the specified threshold. The threshold can, for example, be 1% or 0.1%.

According to an example of the first embodiment of the disclosure, the optimization problem comprises the illumination intensity for different illumination angles of the illumination angle distribution. For example, illumination angles with a higher intensity can be assigned a higher weight in the optimization problem, e.g., in the clustering approaches as described above. Thus, illumination angles with higher illumination intensity have more influence on the selected illumination angles 38 and are more likely to be close to a selected illumination angle 38. In an example, the optimization problem adapts the distribution of the selected illumination angles 38 with respect to the illumination intensity of the illumination angle distribution. Thus, the density of the selected illumination angles 38 is higher in regions of higher illumination intensity. Alternatively, the grid 42 shown for example in FIGS. 4, 5A and 5B can be generated by increasing the density of grid points in regions with higher illumination intensity.

According to an example of the first embodiment of the disclosure, the optimization problem comprises training a machine learning model, which uses the illumination angle distribution as input and generates a number of selected illumination angles 38 as output. In an example, a region-based convolutional neural network (R-CNN) is used which maps an illumination angle distribution to a number of coordinates of selected illumination angles 38. The coordinates can be represented as a list of values or as a binary image of the same size as the illumination angle distribution. Optionally, the machine learning model can use the illumination intensity of the illumination angle distribution as additional input. The training data of the machine learning model can comprise a number of illumination angle distributions, e.g., in the form of a source map as shown in FIGS. 5A and 5B, with corresponding selected illumination angles 38, such that the machine learning model learns to map illumination angle distributions to selected illumination angles 38. Alternatively, the machine learning model can be trained to minimize a loss function, which can, for example, contain the deviation of the obtained simulated aerial image 48 and a reference aerial image 46.

According to an example of the first embodiment of the disclosure, the number of selected illumination angles 38 is below 2%, such as below 1%, for example below 0.5% or even below 0.3% of the illumination angles in the illumination pupil 36. In an example, given a grid 42 comprising 3248 illumination angles, 10 illumination angles are selected. Due to this low number of selected illumination angles 38, only very few electrical near field simulations are used, thereby reducing the computation time.

A method 64 for detecting defects in a photolithography mask 14 according to the second embodiment of the disclosure illustrated in FIG. 9 comprises: acquiring an aerial image of the photolithography mask 14 in an aerial image step 66; simulating an aerial image 48 of a design of the photolithography mask 14 using a computer implemented method 22 according to the first embodiment of the disclosure described above in a simulation step 68; and detecting defects in the photolithography mask 14 by comparing the acquired aerial image to the simulated aerial image in a defect detection step 70. The obtained simulated aerial image can, for example, be compared to the simulated aerial image by computing the difference aerial image and specifying one or more thresholds. Deviations above the one or more thresholds are then viewed as defects. Alternatively, a machine learning model can be trained to detect defects from difference aerial images.

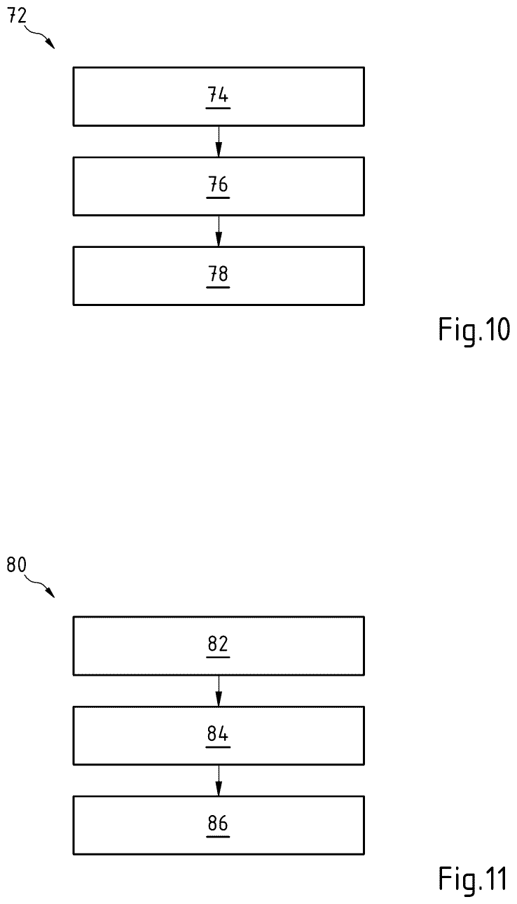

FIG. 10 illustrates a method 72 for assessing the relevance of defects in a photolithography mask 14 according to a third embodiment of the disclosure, the method 72 comprising: providing a charged particle beam image of the photolithography mask 14 comprising one or more defects in an imaging step 74; simulating an aerial image 48 of a design of the photolithography mask 14 using a computer implemented method 22 according to the first embodiment of the disclosure, wherein the charged particle beam image is used as a design of the photolithography mask 14, in a simulation step 76; assessing the relevance of the one or more defects in the photolithography mask 14 using the simulated aerial image in an assessment step 78. A defect is assessed as relevant if it will print on the wafer during the printing process. In contrast, defects that will not print on the wafer are assessed as not relevant. The charged particle beam image is obtained by a charged particle beam device, for example, a Helium ion microscope (HIM), a cross-beam device including FIB and SEM or any charged particle imaging device. The assessment step 78 can comprise the comparison of the simulated aerial image to the charged particle beam image. For example, the one or more locations of the one or more defects in the charged particle beam image can be compared to the corresponding one or more locations in the simulated aerial image. If a defect is not visible in the simulated aerial image it can be concluded that it does not print on the wafer and is, thus, not relevant. If a defect is visible in the simulated aerial image, it can be concluded that it does print on the wafer and, thus, is relevant. The simulated aerial image can also be compared to a reference image, e.g., another simulated or acquired aerial image of the photolithography mask 14 to assess the relevance of the one or more defects. For example, if the simulated aerial image is very similar to the reference image in the location of a defect, the defect can be assessed as not relevant. If the simulated aerial image differs from the reference image in the location of a defect, the defect can be assessed as relevant. The assessment step 78 can, additionally or alternatively, comprise the computation of a critical dimension (CD). The computed CD can be compared to a predefined CD. For example, if the computed CD is lower than the predefined CD in one or more locations these locations can be assessed as relevant defects.

A method 80 for aligning an aerial image of a photolithography mask 14 with a design of the photolithography mask 14 according to a fourth embodiment of the disclosure illustrated in FIG. 11 comprises: acquiring an aerial image of the photolithography mask 14 in an aerial image step 82; simulating an aerial image 48 of the design of the photolithography mask 14 using a computer implemented method 22 according to the first embodiment of the disclosure in a simulation step 84; and aligning the acquired aerial image to the simulated aerial image 48 via image registration in an alignment step 86. In this way, an acquired aerial image can be aligned to a simulated aerial image 48. The shift or displacement field between the acquired aerial image and the simulated aerial image 48 can, for example, be used in the photolithography process for accurately aligning the printed layers of a wafer. In this way, defects can be prevented due to an inaccurate alignment of semiconductor structures in subsequent layers of a wafer.

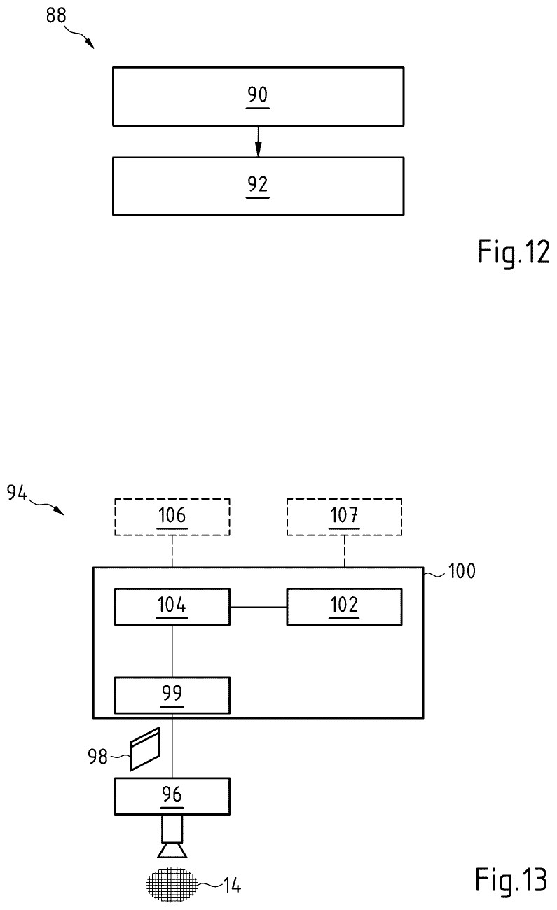

A computer implemented method 88 for generating training data for training a machine learning model, in particular for defect detection or for assessing the relevance of defects in photolithography masks 14 or for aligning photolithography masks 14, according to a fifth embodiment of the disclosure shown in FIG. 12 comprises: obtaining multiple designs of photolithography masks 14 in a design step 90; for each obtained design, simulating an aerial image 48 of the obtained design using a computer implemented method 22 according to the first embodiment of the disclosure and adding the simulated aerial image 48 to the training data in a training data step 92. In case of a one-class machine learning model (e.g., an autoencoder), which is only trained on training samples belonging to the same class, the training data can only comprise defect-free simulated aerial images 48. Otherwise, the training data can comprise simulated aerial images 48 of defect-free and defective designs of photolithography masks 14.

A system for simulating an aerial image of a design of a photolithography mask 14 according to an eighth embodiment of the disclosure comprises a data analysis device comprising at least one memory and at least one processor configured to perform the steps of a computer implemented method according to the first embodiment of the disclosure. The system can comprise a database for loading and/or saving optimized selected illumination angles for illumination angle distributions. Thus, for a specific illumination angle distribution the optimized selected illumination angles 38 can be used again. The system can also comprise a user interface, e.g., for inspecting the selected illumination angles 38 or the simulated aerial image 48.

A system 94 for detecting defects in a photolithography mask 14 according to a ninth embodiment of the disclosure illustrated in FIG. 13 comprises a subsystem 96 for obtaining an aerial image 98 of the photolithography mask 14 and a data analysis device 100 comprising at least one memory 102 and at least one processor 104 configured to perform the steps of a method 64 according to the second embodiment of the disclosure. The system 94 can optionally comprise a database 106 for loading and/or saving optimized selected illumination angles 38 for illumination angle distributions. The subsystem 96 for obtaining an aerial image 98 of the photolithography mask 14 can comprise an aerial image acquisition system. Alternatively, the subsystem 96 can comprise a database or any other memory comprising an aerial image 98 of the photolithography mask 14, and the subsystem 96 can be configured to load the aerial image 98 from the database or memory. The subsystem 96 for obtaining an aerial image 98 of the photolithography mask 14 can provide an aerial image 98 to the data analysis device 100. The data analysis device 100 includes a processor 104, e.g., implemented as a CPU or GPU. The processor 104 can receive the aerial image 98 via an interface 99. The processor 104 can load program code from a memory 102, e.g., program code for executing a method 64 for detecting defects according to the second embodiment of the disclosure as described above. The processor 104 can execute the program code. The system 94 can also comprise a user interface 107, e.g., for inspecting the selected illumination angles 38, a simulated aerial image 48 or the detected defects.

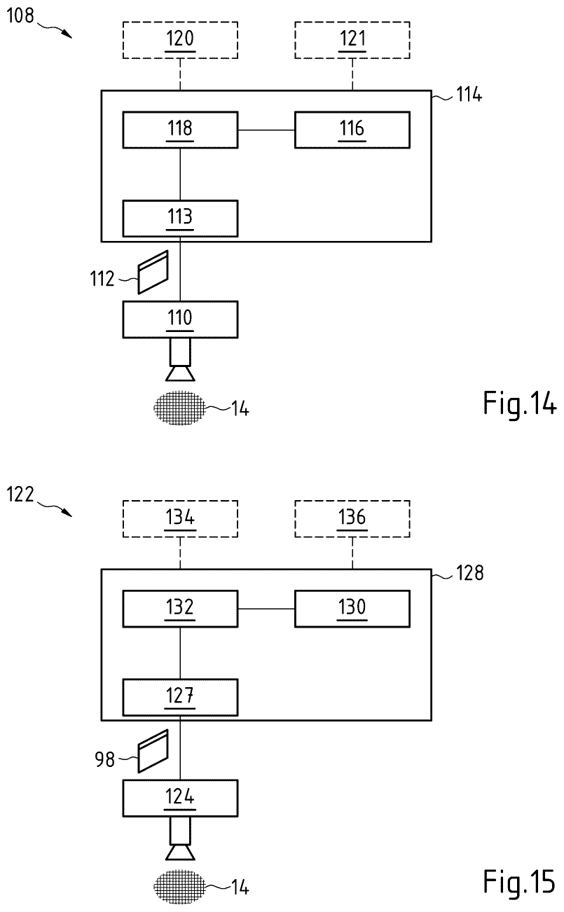

A system 108 for assessing the relevance of defects in a photolithography mask 14 according to a tenth embodiment of the disclosure illustrated in FIG. 14 comprises a subsystem 110 for obtaining a charged particle beam image 112 of the photolithography mask 14 and a data analysis device 114 comprising at least one memory 116 and at least one processor 118 configured to perform the steps of a method 72 according to the third embodiment of the disclosure.

The subsystem 108 for obtaining a charged particle beam image 112 of the photolithography mask 14 can comprise a charged particle beam device, for example, a Helium ion microscope (HIM), a cross-beam device including FIB and SEM or any charged particle imaging device. Alternatively, the subsystem 108 can comprise a database or any other memory comprising a charged particle beam image 112 of the photolithography mask 14, and the subsystem 108 can be configured to load the charged particle beam image 112 from the database or memory. The subsystem 108 for obtaining a charged particle beam image 112 of the photolithography mask 14 can provide a charged particle beam image 112 to the data analysis device 114. The data analysis device 114 includes a processor 118, e.g., implemented as a CPU or GPU. The processor 118 can receive the charged particle beam image 112 via an interface 113. The processor 118 can load program code from a memory 116, e.g., program code for a method 72 for assessing the relevance of defects according to the third embodiment of the disclosure as described above. The processor 118 can execute the program code. The system 108 can optionally comprise a database 120 for loading and/or saving optimized selected illumination angles 38 for illumination angle distributions. The system 108 can also comprise a user interface 121, e.g., for inspecting the selected illumination angles 38, the charged particle beam image 112 or the defects and their relevance.

A system 122 for aligning an aerial image 98 of a photolithography mask 14 with a design of the photolithography mask according to an eleventh embodiment of the disclosure illustrated in FIG. 15 comprises a subsystem 124 for obtaining an aerial image 98 of the photolithography mask 14 and a data analysis device 128 comprising at least one memory 130 and at least one processor 132 configured to perform the steps of a method 80 according to the fourth embodiment of the disclosure. The subsystem 124 for obtaining an aerial image 98 of the photolithography mask 14 can comprise an aerial image acquisition system. Alternatively, the subsystem 124 can comprise a database or any other memory comprising an aerial image 98 of the photolithography mask 14, and the subsystem 124 can be configured to load the aerial image 98 from the database or memory. The subsystem 124 for obtaining an aerial image 98 of the photolithography mask 14 can provide an aerial image 98 to the data analysis device 128. The data analysis device 128 includes a processor 132, e.g., implemented as a CPU or GPU. The processor 132 can receive the aerial image 98 via an interface 127. The processor 132 can load program code from a memory 130, e.g., program code for executing a method 80 for aligning an aerial image 98 of a photolithography mask 14 according to the fourth embodiment of the disclosure as described above. The processor 132 can execute the program code. The system 122 can optionally comprise a database 134 for loading and/or saving optimized selected illumination angles 38 for illumination angle distributions. The system 122 can also comprise a user interface 136, e.g., for inspecting the selected illumination angles 38, a simulated aerial image 48 or an alignment.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

The disclosure can be described by the following clauses:
1. A computer implemented method 22 for simulating an aerial image 48 of a design of a photolithography mask 14 in a photolithography system 10, 10′, the photolithography mask 14 being illuminated by an illuminating optical unit by using a light source 12 emitting illuminating radiation, the illuminating optical unit having a pupil plane 33, the method comprising:
   a. Obtaining an illumination angle distribution in the pupil plane 33 of the light source 12;
   b. Selecting a number of illumination angles from the illumination angle distribution by solving an optimization problem;
   c. For each selected illumination angle 38, simulating an electromagnetic near field of the design of the photolithography mask 14 illuminated by incident electromagnetic waves of the selected illumination angle 38 in a near field plane;
   d. For at least one further illumination angle 40 of the illumination angle distribution in the pupil plane 33 of the light source 12, which was not selected, approximating an electromagnetic near field of the design of the photolithography mask 14 illuminated by incident electromagnetic waves of the respective illumination angle using the simulated electromagnetic near fields for the selected illumination angles 38; and
   e. Obtaining the aerial image 48 of the design of the photolithography mask 14 by superimposing the intensities obtained by imaging the simulated electromagnetic near fields and the at least one approximated electromagnetic near field into a wafer plane 20.
2. The method of clause 1, wherein the illumination angle distribution is subsampled to generate a discrete set of illumination angles corresponding to electromagnetic plane waves which fulfill periodic boundary conditions in the near field plane.
3. The method of any one of the preceding clauses, wherein the optimization problem comprises optimizing an objective function containing a measurement related to the approximation error of the simulated aerial image 48.
4. The method of any one of the preceding clauses, wherein the optimization problem comprises optimizing an objective function containing the number of selected illumination angles 38.
5. The method of clause any one of the preceding clauses, wherein the optimization problem comprises a deviation of one or more closest selected illumination angles 38 from one or more further illumination angles 40 in the illumination pupil 36.
6. The method of any one of the preceding clauses, wherein the optimization problem comprises clustering illumination angles of the illumination angle distribution in the pupil plane 33.
7. The method of clause 6, wherein the optimization problem comprises a k-means clustering of the illumination angles of the illumination angle distribution in the pupil plane 33.
8. The method of clause 6, wherein the optimization problem comprises a hierarchical clustering of the illumination angles of the illumination angle distribution in the pupil plane 33.
9. The method of any one of the preceding clauses, wherein the optimization problem comprises a deviation of the obtained aerial image 48 and a reference aerial image 46.
10. The method of any one of the preceding clauses, wherein the optimization problem comprises the illumination intensity for different illumination angles of the illumination angle distribution.
11. The method of clause 10, wherein the optimization problem adapts the distribution of the selected illumination angles 38 with respect to the illumination intensity of the illumination angle distribution.
12. The method of any one of the preceding clauses, wherein the optimization problem comprises training a machine learning model, which uses the illumination angle distribution as input and generates a number of selected illumination angles 38 as output.
13. The method of any one of the preceding clauses, wherein approximating an electromagnetic near field of the design of the photolithography mask 14 for a further illumination angle 40, which was not selected, comprises shifting the mask spectrum of the simulated electromagnetic near field of the closest selected illumination angle 38.
14. The method of any one of the preceding clauses, wherein approximating an electromagnetic near field of the design of the photolithography mask 14 for a further illumination angle 40, which was not selected, comprises interpolation or regression of mask spectra of simulated electromagnetic near fields.
15. The method of any one of the preceding clauses, wherein the number of selected illumination angles 38 is below 2%.
16. A method 64 for detecting defects in a photolithography mask 14, the method comprising:
   Acquiring an aerial image 98 of the photolithography mask 14 using an aerial image acquisition system;
   Simulating an aerial image 48 of a design of the photolithography mask 14 using a method according to any one of the preceding clauses; and
   Detecting defects in the photolithography mask 14 by comparing the acquired aerial image 98 to the simulated aerial image 48.
17. The method of clause 16, further comprising repairing the detected defects in the photolithography mask 14.
18. A method 72 for assessing the relevance of defects in a photolithography mask 14, the method comprising:
   Acquiring a charged particle beam image 112 of the photolithography mask 14 comprising one or more defects using a charged particle beam image acquisition system;
   Simulating an aerial image 48 of a design of the photolithography mask 14 using a computer implemented method 22 according to any one of clauses 1 to 15, wherein the charged particle beam image 112 is used as a design of the photolithography mask 14; and
   Assessing the relevance of the one or more defects in the photolithography mask 14 using the simulated aerial image 48.
19. A method for manufacturing a photolithography mask 14 comprising
   Simulating an aerial image 48 of a design of a photolithography mask 14 in a photolithography system 10, 10′ using a computer implemented method 22 according to any one of clauses 1 to 15,
   Detecting defects in the design of the photolithography mask 14,
   Improving the design of the photolithography mask 14,
   Manufacturing the photolithography mask 14 using the improved design.
20. A method 80 for aligning an aerial image 98 of a photolithography mask 14 with a design of the photolithography mask 14, the method comprising:
   Acquiring an aerial image 98 of the photolithography mask 14 using an aerial image acquisition system;
   Simulating an aerial image 48 of the design of the photolithography mask 14 using a computer implemented method 22 according to any one of clauses 1 to 15; and
   Aligning the acquired aerial image 98 to the simulated aerial image 48 by means of image registration.
21. A non-transitory computer-readable medium, comprising a stored computer program executable by a computing device, the computer program comprising code for executing a method of any one of clauses 1 to 15.
22. A computer program product comprising instructions which, when the program is executed by a computer, cause the computer to carry out a method of any one of clauses 1 to 15.
23. A system for simulating an aerial image 48 of a design of a photolithography mask 14, the system comprising a data analysis device comprising at least one memory and at least one processor configured to perform the steps of a computer implemented method 22 according to any one of clauses 1 to 15.
24. A system 94 for detecting defects in a photolithography mask 14, the system 94 comprising a subsystem 100 for obtaining an aerial image 98 of the photolithography mask 14 and a data analysis device 100 comprising at least one memory 102 and at least one processor 104 configured to perform the steps of the computer implemented method 64 of clause 16.
25. A system 108 for assessing the relevance of defects in a photolithography mask 14, the system 108 comprising a subsystem 110 for obtaining a charged particle beam image 112 of the photolithography mask 14 and a data analysis device 114 comprising at least one memory 116 and at least one processor 118 configured to perform the steps of the computer implemented method 72 of clause 18.
26. A system 122 for aligning an aerial image 98 of a photolithography mask 14 with a design of the photolithography mask 14, the system 122 comprising a subsystem 124 for obtaining an aerial image 98 of the photolithography mask 14 and a data analysis device 124 comprising at least one memory 130 and at least one processor 132 configured to perform the steps of the computer implemented method 80 of clause 19.

In summary, the disclosure relates to a computer implemented method 22 for simulating an aerial image 48 of a design of a photolithography mask 14 comprising: obtaining an illumination angle distribution in the pupil plane 33 of the light source 12; selecting a number of illumination angles by solving an optimization problem; for each selected illumination angle 38, simulating an electromagnetic near field; for at least one further illumination angle 40 of the illumination angle distribution in the pupil plane 33 of the light source 12 approximating an electromagnetic near field; and obtaining the simulated aerial image 48 of the design of the photolithography mask 14 by superimposing the intensities obtained by imaging the electromagnetic near fields into a wafer plane 20. The disclosure also relates to systems 94, 108, 122 for detecting defects or for assessing the relevance of defects or for aligning aerial images 98.

Reference number list

| | |
|---|---|
| 10, 10′ | Photolithography system |
| 12 | Light source |
| 14 | Photolithography mask |
| 16 | Illumination optics |
| 18 | Projection optics |
| 20 | Wafer plane |
| 22 | Computer implemented method |
| 24 | Illumination distribution step |
| 26 | Optimization step |
| 28 | Near field simulation step |
| 30 | Near field approximation step |
| 32 | Aerial image simulation step |
| 33 | Pupil plane |
| 34 | Imaging pupil |
| 35 | Equidistant selected illumination angles |
| 36 | Illumination pupil |
| 37 | Optimized selected illumination angles |
| 38 | Selected illumination angle |
| 39 | Illumination intensity scale |
| 40 | Further illumination angle |
| 42 | Grid |
| 44 | Segment |
| 46 | Reference aerial image |
| 48 | Simulated aerial image |
| 50 | Difference image |
| 52 | Root mean squared error |
| 54 | Maximum error |
| 56 | Root mean squared error |
| 58 | Maximum error |
| 60 | Horizontal axis |
| 62 | Vertical axis |
| 64 | method |
| 66 | Aerial image step |
| 68 | Simulation step |
| 70 | Defect detection step |
| 72 | method |
| 74 | Imaging step |
| 76 | Simulation step |
| 78 | Assessment step |
| 80 | method |
| 82 | Aerial image step |
| 84 | Simulation step |
| 86 | Alignment step |
| 88 | Computer implemented method |
| 90 | Design step |
| 92 | Training data step |
| 94 | System |
| 96 | Subsystem |
| 98 | Aerial image |
| 99 | Interface |
| 100 | Data analysis device |
| 102 | Memory |
| 104 | Processor |
| 106 | Database |
| 107 | User interface |
| 108 | System |
| 110 | Subsystem |
| 112 | Charged particle beam image |
| 113 | Interface |
| 114 | Data analysis device |
| 116 | Memory |
| 118 | Processor |
| 120 | Database |
| 121 | User interface |
| 122 | System |
| 124 | Subsystem |
| 127 | Interface |
| 128 | Data analysis device |
| 130 | Memory |
| 132 | Processor |
| 134 | Database |
| 136 | User interface |

What is claimed is:

1. A computer implemented method to simulate an aerial image of a design of a photolithography mask in a photolithography system, the photolithography mask being illuminated by an illuminating optical unit using a light source emitting illuminating radiation, the illuminating optical unit having a pupil plane, the method comprising:
a. obtaining an illumination angle distribution in the pupil plane of the light source;
b. selecting a number of illumination angles from the illumination angle distribution by solving an optimization problem;
c. for each selected illumination angle, simulating an electromagnetic near field of the design of the photolithography mask illuminated by incident electromagnetic waves of the selected illumination angle in a near field plane;
d. for a non-selected illumination angle of the illumination angle distribution in the pupil plane of the light source, approximating an electromagnetic near field of the design of the photolithography mask illuminated by incident electromagnetic waves of the non-selected illumination angle using the simulated electromagnetic near fields for the selected illumination angles; and
e. obtaining the simulated aerial image of the design of the photolithography mask by superimposing the intensities obtained by imaging the simulated electromagnetic near fields and the approximated electromagnetic near field into a wafer plane.

2. The method of claim 1, wherein the illumination angle distribution is subsampled to generate a discrete set of illumination angles corresponding to electromagnetic plane waves which fulfill periodic boundary conditions in the near field plane.

3. The method of claim 1, wherein the optimization problem comprises optimizing an objective function comprising an approximation error.

4. The method of claim 1, wherein the optimization problem comprises optimizing an objective function comprising a measurement related to the approximation error of the simulated aerial image.

5. The method of claim 1, wherein the optimization problem comprises optimizing the number of selected illumination angles.

6. The method of claim 1, wherein the optimization problem comprises a deviation of one or more selected illumination angles from one or more further illumination angles in the illumination pupil.

7. The method of claim 1, wherein the optimization problem comprises clustering illumination angles of the illumination angle distribution in the pupil plane.

8. The method of claim 1, wherein the optimization problem comprises a k-means clustering of the illumination angles of the illumination angle distribution in the pupil plane.

9. The method of claim 1, wherein the optimization problem comprises a hierarchical clustering of the illumination angles of the illumination angle distribution in the pupil plane.

10. The method of claim 1, wherein the optimization problem comprises a deviation of the obtained simulated aerial image from a reference aerial image.

11. The method of claim 1, wherein the optimization problem comprises an illumination intensity for different illumination angles of the illumination angle distribution.

12. The method of claim 11, wherein the optimization problem adapts the distribution of the selected illumination angles with respect to the illumination intensity of the illumination angle distribution.

13. The method of claim 1, wherein the optimization problem comprises training a machine learning model, which uses the illumination angle distribution as input and generates a number of selected illumination angles as output.

14. The method of claim 1, wherein d comprises shifting the mask spectrum of the simulated electromagnetic near field of the closest selected illumination angle.

15. The method of claim 1, wherein d comprises interpolation or regression of mask spectra of simulated electromagnetic near fields.

16. The method of claim 1, wherein the number of selected illumination angles is less than 2% of the illumination angles in the illumination pupil plane.

17. The method of claim 1, further comprising:
acquiring an aerial image of the photolithography mask using an aerial image acquisition system; and
detecting defects in the photolithography mask by comparing the acquired aerial image of the photolithography mask to the simulated aerial image of the photolithography mask.

18. The method of claim 17, further comprising repairing the detected defects in the photolithography mask.

19. The method of claim 1, further comprising:
acquiring a charged particle beam image of the photolithography mask comprising one or more defects using a charged particle beam image acquisition system; and
assessing the relevance of the one or more defects in the photolithography mask by comparing the acquired image of the photolithography mask to the simulated aerial image of the photolithography mask.

20. The method of claim 1, further comprising:
detecting defects in the design of the photolithography mask;
improving the design of the photolithography mask based on the detected defects; and
manufacturing a photolithography mask using the improved design.

21. The method of claim 1, further comprising:
acquiring an aerial image of the photolithography mask using an aerial image acquisition system; and
aligning the acquired aerial image to the simulated aerial image using image registration.

22. One or more machine-readable hardware storage devices comprising instructions that are executable by one or more processing devices to perform operations comprising the method of claim 1.

23. A system, comprising:
one or more processing devices; and
one or more machine-readable hardware storage devices comprising instructions that are executable by the one or more processing devices to perform operations comprising the method of claim 1.
